(19) United States
(12) Patent Application Publication
(10) Pub. No.: US 2009/0057687 A1
(43) Pub. Date: Mar. 5, 2009

(54) LIGHT EMITTING DIODE MODULE

(75) Inventors: Lingli Wang, Eindhoven (NL); Joseph Ludovicus Antonius Maria Sormani, Eindhoven (NL); Peter Hubertus Franciscus Deurenberg, Eindhoven (NL); Eduard Johannes Meijer, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/296,579

(22) PCT Filed: Apr. 3, 2007
(86) PCT No.: PCT/IB2007/051184

§ 371 Date: Oct. 9, 2008

(30) Foreign Application Priority Data
Apr. 10, 2006 (EP) 06112437.6

(51) Int. Cl. H01L 33/00; H01L 21/00

(52) U.S. Cl. 257/82; 438/25; 257/E33.076; 257/E21.001

(57) ABSTRACT

The present invention relates to a light emitting diode (LED) module (10) comprising a substrate (12) having plural indents (14) and flattish portions (20) in between the indents, and LEDs (16) mounted in the indents. The LED module is characterized by at least one of sensors (22) and additional LEDs (32) provided at the flattish portions. This allows increased sensor detection accuracy and/or color compensation.

The present invention also relates to a method for the manufacturing of such an LED module.

The present invention relates to a light emitting diode (LED) module comprising a substrate having plural indents and flattish portions in between the indents and LEDs mounted in the indents. The present invention also relates to a method for the manufacturing of such an LED module.

An example of an LED module of the above type is disclosed in the document U.S. Pat. No. 6,611,000, wherein plural recesses are formed on a substrate, each recess accommodating an LED. All LEDs are of the same color. A single photodetector is further mounted at the rim of the substrate next to the recesses and LEDs. The LEDs and the photodetector are covered with a transparent resin layer. The function of the single photodetector is to detect an optical output propagating through the transparent resin layer from the LEDs and to feed the output back to control and drive circuits, whereby the output of the LEDs can be adjusted in case the detected output differs from a desired output. Changed LED output can for example be due to changed operating temperature, ageing, etc.

However, a drawback with the LED module in U.S. Pat. No. 6,611,000 is that the single photodetector is most sensitive to the LED it is closest to, which may result in an inaccurate detection and subsequent LED output adjustment. For example, if the LED closest to the photodetector is too low on flux while the other more distant LEDs emits light at a desired flux level, the detection will indicate that the LED output should be increased, even though the overall flux level may be acceptable since the other more distant LEDs emits light at the desired flux level.

It is an object of the present invention to overcome this problem, and to provide an improved LED module allowing more accurate detection of LED characteristics. It is another object of the invention to provide an LED module allowing convenient addition of color.

These and other objects that will be evident from the following description are achieved by means of an LED module, and a method for the manufacturing of such an LED module, according to the appended claims.

According to an aspect of the invention, there is provided an LED module comprising a substrate having plural indents and flattish portions in between the indents, and LEDs mounted in the indents, characterized in that the LED module further comprises at least one sensors and/or at least one additional LED, which are/is provided at the flattish portions.

The invention is based on the understanding that the flattish portions of the substrate between the indents offer a feasible opportunity to place additional components thereat. Placing sensors at the flattish portions allows local detections at various positions of the LED module, which detections can be averaged to a more accurate value compared to a case where a single photodetector at the edge of the substrate is used. Also, since a sensor is placed close to each LED, the LED module can be scaled up to a large size with maintained accurate detection of local LED characteristics. Also, in case LEDs of different colors are used, each color can get its own sensor, which allows for color specific feedback. Further, placing additional LEDs at the flattish portions allows for generation of additional flux as well as compensation of the LED efficacy when temperature is raised during operation. For example red LEDs' output decreases at raised temperature, which can be compensated by providing additional red LEDs. In this way, the amount of red flux can be adjusted to keep homogenous color mixing. At each given flattish portion there can be positioned a sensor only, an additional LED only, both a sensor and an additional LED, or it can be left empty. Thus, various configurations are possible.

The sensors can include flux sensors for measuring the lumen output of the LEDs to provide (local) flux feedback, or temperature sensors for measuring the LEDs' temperature to provide (local) temperature feedback. The flux sensor can for example be a photodiode (filtered or unfiltered), a CMOS-sensor, a CCD, etc. The temperature sensor can for example be an NTC temperature sensor, a PTC temperature sensor or diode junction temperature sensor.

The sensors can be placed on the very top of the flattish portions between the indents, or in recesses in the flattish portions. In the former case, for flux sensors, a shielding is preferably provided around the sensor to insulate the sensor from direct light from the LEDs. Optics placed above the substrate, such as a reflector or collimator, ensures that a sufficient amount of light returns to the sensor for allowing proper detection. In the latter case, the recesses are preferably etched into the flattish portions of the substrate, in this case advantageously a silicon substrate, and sized to partly bury a flux sensor placed in the recess, again to insulate the sensor from direct light from the LEDs. Thus, in the latter case, no additional shielding is necessary. Further, any additional LEDs are preferably mounted on top of the flattish portions, for maximum out coupling of light.

The indents of the substrate are preferably achieved by etching before the various components are mounted to the substrate. Also preferably, the indents of the substrate have sloping side surfaces. The sloping side surfaces can be planar or curved. The sloping side surfaces allow pre-collimation of the light emitted from the LED(s) accommodated in the indent by using the side surface as a reflector. Further, in case plural LEDs are accommodated in the indent, such as a red, green and blue LED, the sloping side surfaces also serve to pre-mix the light emitted from the different LEDs, i.e. the indent functions as a color-mixing chamber.

According to another aspect of the invention, there is provided a method for the manufacturing of an LED module, comprising preparing a substrate by etching plural indents into the substrate such that flattish portions are formed in between the indents, mounting LEDs in the indents, and providing at least one of sensors and additional LEDs at the flattish portions. This method offers similar advantages as obtained with the previously discussed aspect of the invention.

This and other aspects of the present invention will now be described in more detail, with reference to the appended drawings showing currently preferred embodiments of the invention.

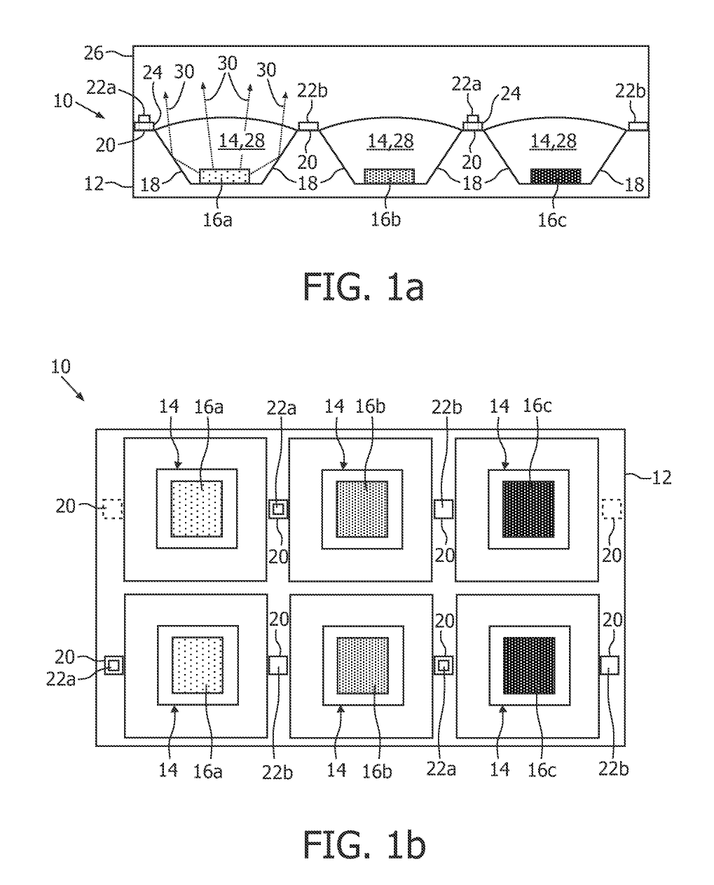

FIG. 1a is a schematic cross-sectional side view of an LED module according to an embodiment of the invention,

FIG. 1b is a schematic top view of the LED module of FIG. 1a,

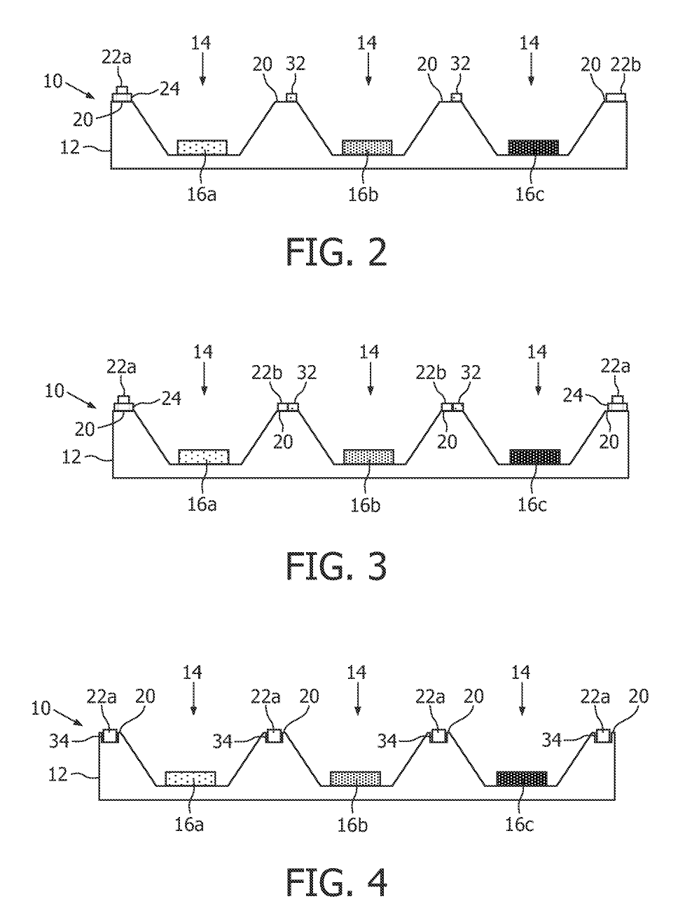

FIGS. 2-5 are schematic cross-sectional side views of LED modules according to other embodiments of the invention, and

FIG. 6 is a flow chart of a method for the manufacturing of an LED module according to the invention.

FIG. 1a is a schematic cross-sectional side view of an LED module 10 according to an embodiment of the invention. The LED module 10 comprises a pre-etched substrate 12 with a plurality of indents 14. The indents 14 are preferably pre-etched. In each indent 14, there is provided an LED generally designated 16, in this case a red LED 16a, a green LED 16b, and a blue LED 16c. The LEDs can be intrinsic LEDs or phosphor converted LEDs. Each LED 16 is mounted to a bottom surface of the indent 14. The indents 14 have sloping side surfaces 18. The sloping side surfaces 18 in FIG. 1a are planar, but they can alternatively be curved. The sloping side surfaces 18 and optionally the bottom surfaces of the indents 14 are preferably reflective, e.g. provided with a reflective coating.

Between the indents 14, and next to the outer indents, there are formed essentially flat portions 20 onto which sensors generally designated 22 are mounted. The sensors 22 can include flux sensors 22a and/or temperature sensors 22b. The LED module 10 in FIG. 1 comprises two each. A shielding 24 is provided around each flux sensor 22a to insulate the sensor from direct light from the LEDs 16. The LED module 10 further comprises optics 26 placed above the substrate 12. The optics 26 can for example be a reflector or a collimator. The spaces between the substrate 12 and optics 26 are filled with encapsulant 28.

Upon operation of the LED module 10, light emitted from an LED 16 is pre-collimated by the sloping side surfaces 18 of the indent 14 in which it is accommodated, as indicated by exemplary ray traces 30. Light emitted from the LEDs 16 propagates through the encapsulant 28 and the optics 26 and is detected by the flux sensors 22a. The optics 26 ensures that a sufficient amount of light returns to the sensor to allow proper detection. In the LED module 10 of FIG. 1, the flux is detected at two different places, thus yielding two local flux detections or measurements and/or a more accurate averaged measure of the overall flux. At the same time, the temperature is detected at two different places as well by means of the temperature sensors 22b, again yielding two local temperature measurements and/or a more accurate averaged measure of the overall temperature. The data from the various sensors 22 is then fed to a control and drive circuitry (not shown) of the LED module 10, wherein the data by means of known techniques are used to adjust the LEDs in order to provide a desired output in regard to color, brightness, etc. Examples of such known techniques, such as temperature feed forward (TFF) and flux feedback (FFB), that advantageously could be used in relation to the present invention, are disclosed in the publication “Achieving color point stability in RGB multi-chip LED modules using various color control loops”, P. Deurenberg et al., Proc. SPIE Vol. 5941, 59410C (Sep. 7, 2005).

FIG. 1b is a schematic top view of the LED module of FIG. 1a. As can be seen, it is not necessary to place a sensor 22 or other component at each flattish portion 20. Instead, the number and types of sensors should be selected based on a desired level of accuracy and preciseness of the detections. More sensors yield more accurate and precise measurements. For clarity, the optics 26 and encapsulant 28 have been omitted in FIG. 1b.

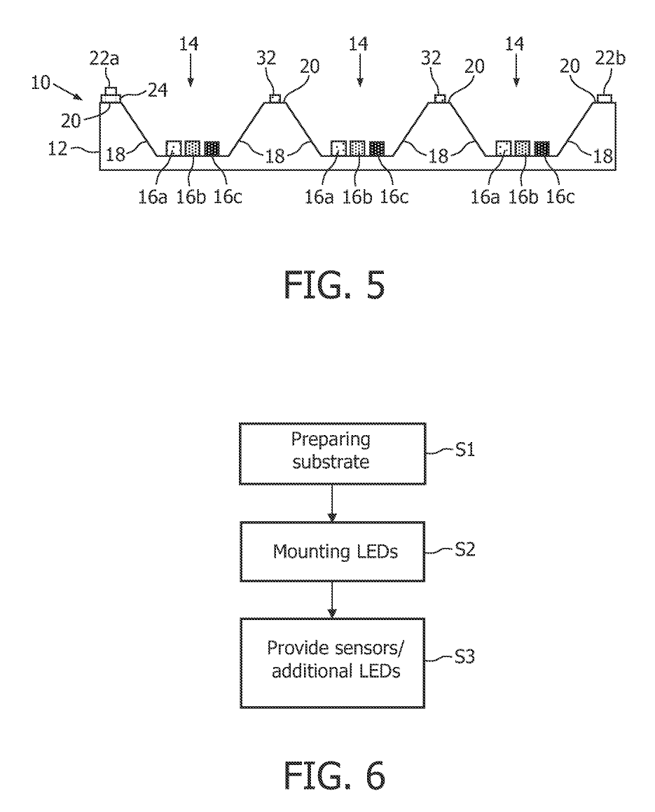

FIGS. 2-5 are schematic cross-sectional side views of LED modules according other embodiments of the invention. The LED modules in FIGS. 2-5 are similar to the LED module of FIG. 1, and only pertinent differences will be described. The optics 26 and encapsulant 28 have further been omitted in FIGS. 2-5 for clarity. In FIG. 2, instead of sensors 22, there is provided additional LEDs 32 on the middle two flattish portions 20. The additional LEDs 32 can be used to generate additional flux or to compensate for flux output decreases with increased temperature (for example during operation of the LED module). Thus, the additional LEDs can compensate for this decrease in output. Also, both a sensor 22 and an additional LED 32 can be positioned on the same flattish surface 20, as illustrated in FIG. 3. Further, the flattish portions 20 of the substrate 12, in this case preferably a silicon substrate, can be provided with etched recesses 34 to accommodate and at least partly bury the flux sensors 22a, as illustrated in FIG. 4. This is a somewhat more complex substrate, but the additional shieldings 24 shown in for example FIG. 1 can be omitted. Finally, in FIG. 5, plural LEDs 16 are accommodated in the indents 14. In FIG. 5, the plural LEDs 16 in each indent 14 comprise a red LED 16a, a green LED 16b, and a blue LED 16c. In this embodiment, the sloping side surfaces 18 of the indents 14 also serve to pre-mix the light emitted from the different LEDs 16, i.e. the indent 14 functions as a color-mixing chamber. The light from the LEDs 16a, 16b and 16c can for example be mixed to a whitish light.

A method for the manufacturing of any of the LED modules of the invention described above is summarized in the flow chart of FIG. 6. The method comprises the steps of: preparing a substrate by etching plural indents into the substrate such that flattish portions are formed in between the indents (step S1), mounting LEDs in the indents (step S2), and provide at least one of sensors and additional LEDs at the flattish portions (step S3). The LED module according to the present invention can advantageously be used in general lighting applications and automotive lighting applications.

The person skilled in the art realizes that the present invention by no means is limited to the preferred embodiments described above. On the contrary, many modifications and variations are possible within the scope of the appended claims. For example, an LED module with only additional LEDs at the flattish portions, but no sensors, could be envisaged.

1. A light emitting diode (LED) module (10), comprising a substrate (12) having plural indents (14) and flattish portions (20) in between the indents, and LEDs (16) mounted in the indents, characterized in that the LED module further comprises at least one sensor (22) and/or at least one additional LED (32), which are/is provided at the flattish portions.

2. An LED module according to claim 1, wherein the sensors include flux sensors (22a).

3. An LED module according to claim 1, wherein the sensors include temperature sensors (22b).

4. An LED module according to claim 1, wherein at least one sensor is mounted on top of the flattish portions.

5. An LED module according to claim 2, wherein a shielding (24) is provided around the sensor.

6. An LED module according to claim 2, wherein at least one sensor is mounted in a recess (34) in the flattish portion such that the sensor is at least partly buried.

7. An LED module according to claim 1, wherein the additional LEDs are mounted on top of the flattish portions.

8. An LED module according to claim 1, wherein the additional LEDs are red.

9. An LED module according to claim 1, wherein the indents are achieved by etching.

10. An LED module according to claim 1, wherein the indents have sloping side surfaces (18).

11. An LED module according to claim 1, wherein at least one indent accommodates a single LED.

12. An LED module according to claim 1, wherein at least one indent accommodates plural LEDs.

13. An LED module according to claim 1, wherein the LEDs include red (16a), green (16b), and blue (16c) LEDs.

14. A method for the manufacturing of a light emitting diode (LED) module, comprising:
preparing a substrate by etching plural indents into the substrate such that flattish portions are formed in between the indents,
mounting LEDs in the indents, and
providing at least one sensor and/or at least one additional LED at the flattish portions.
